(19) United States
(12) Patent Application Publication
(10) Pub. No.: US 2024/0339287 A1
(43) Pub. Date: Oct. 10, 2024

(54) APPARATUS, SYSTEM AND TECHNIQUES FOR MASS ANALYZED ION BEAM

(71) Applicant: Applied Materials, Inc., Santa Clara, CA (US)

(72) Inventors: Alexandre Likhanskii, Malden, MA (US); Nirbhav Singh Chopra, Princeton, NJ (US); Peter F. Kurunczi, Cambridge, MA (US); Anthony Renau, West Newbury, MA (US); Joseph C. Olson, Beverly, MA (US); Frank Sinclair, Hartland, ME (US)

(73) Assignee: Applied Materials, Inc., Santa Clara, CA (US)

(21) Appl. No.: 18/131,271

(22) Filed: Apr. 5, 2023

(51) Int. Cl. H01J 37/05; H01J 37/147; H01J 37/317

(52) U.S. Cl. CPC H01J 37/05; H01J 37/1472; H01J 37/3171; H01J 37/12; H01J 2237/053; H01J 2237/057; H01J 2237/1207; H01J 2237/2505

(57) ABSTRACT

An apparatus may include an electrodynamic mass analysis (EDMA) assembly disposed downstream from the convergent ion beam assembly. The EDMA assembly may include a first stage, comprising a first upper electrode, disposed above a beam axis, and a first lower electrode, disposed below the beam axis, opposite the first upper electrode. The EDMA assembly may also include a second stage, disposed downstream of the first stage and comprising a second upper electrode, disposed above the beam axis, and a second lower electrode, disposed below the beam axis. The EDMA assembly may further include a deflection assembly, disposed between the first stage and the second stage, the deflection assembly comprising a blocker, disposed along the beam axis, an upper deflection electrode, disposed on a first side of the blocker, and a lower deflection electrode, disposed on a second side of the blocker.

### FIELD OF THE DISCLOSURE

The disclosure relates generally to ion beam apparatus and more particularly to ion implanters having mass analysis.

### BACKGROUND OF THE DISCLOSURE

Ion implantation is a process of introducing dopants or impurities into a substrate via bombardment. Ion implantation systems (“ion implanters”) may comprise an ion source and a substrate stage or process chamber, housing a substrate to be implanted. The ion source may comprise a chamber where ions are generated. Beamline ion implanters may include a series of beam-line components, for example, a mass analyzer, a collimator, and various components to accelerate or decelerate the ion beam.

A useful function of an ion implanter beamline is to separate ions of different masses so that an ion beam may be formed having the desired ions for treating the work piece or substrate, while undesirable ions are intercepted in a beamline component and do not reach the substrate. In known systems, this mass analysis function is provided by an analyzing magnet, which component bends a beam of ions that all have the same energy in a curve whose radius depends on the ion mass, thus achieving the required separation. Magnets of this kind, however, are large, expensive and heavy and represent a significant fraction of the cost and power consumption of an ion implanter.

For relatively lower energy ion implantation, such as energy below approximately 50 keV, compact ion beam systems have been developed. These ion beam systems may include a plasma chamber acting as ion source, and placed adjacent a process chamber, housing the substrate to be implanted. An ion beam may be extracted from the plasma chamber using an extraction grid or other extraction optics to provide an ion beam to the substrate, with a desired beam shape, such as a ribbon beam. In these latter systems, mass analysis may be omitted because of size/space considerations for installing a magnetic analyzer, as discussed above, as well as cost. Thus, the use of such compact ion beam systems may be limited to applications where purity of implanting species is not a strict requirement.

Recently, an approach for ion beam processing system has been proposed, wherein an electrodynamic mass analysis (EDMA) component is used to generate a mass analyzed ion beam in a more compact ion beam processing apparatus than known beamline ion implanters. This approach applies a high frequency field to filter out ions of unwanted mass. However EDMA designs conceived of to date may not generate acceptably high flux for ions of the targeted mass, especially when operating at high overall beam current.

With respect to these and other considerations, the present disclosure is provided.

### BRIEF SUMMARY

In one embodiment, an apparatus is provided. The apparatus may include an electrodynamic mass analysis (EDMA) assembly disposed downstream from the convergent ion beam assembly. The EDMA assembly may include a first stage, comprising a first upper electrode, disposed above a beam axis, and a first lower electrode, disposed below the beam axis, opposite the first upper electrode. The EDMA assembly may also include a second stage, disposed downstream of the first stage and comprising a second upper electrode, disposed above the beam axis, and a second lower electrode, disposed below the beam axis. The EDMA assembly may further include a deflection assembly, disposed between the first stage and the second stage, the deflection assembly comprising a blocker, disposed along the beam axis, an upper deflection electrode, disposed on a first side of the blocker, and a lower deflection electrode, disposed on a second side of the blocker.

In another embodiment, an ion beam processing system is provided, including an ion source chamber, to generate an ion beam as a continuous ion beam, a convergent beam assembly, to output the ion beam as a convergent ion beam along a beam axis, and an electrodynamic mass analysis (EDMA) assembly. The EDMA assembly may include a first stage, to receive the convergent ion beam and apply a first RF signal between a first upper electrode and a first lower electrode, as well as a second stage, disposed downstream of the first stage, to apply a second RF signal between a second upper electrode and a second lower electrode. The EDMA assembly may also include a deflection assembly, disposed between the first stage and the second stage, and comprising a blocker, disposed along the beam axis, an upper deflection electrode, disposed on a first side of the blocker, and a lower deflection electrode, disposed on a second side of the blocker.

In another embodiment, a method may include directing an ion beam as a continuous ion beam along a beam axis into a first stage of an electrodynamic mass analysis (EDMA) assembly. The method may include deflecting the ion beam along a trajectory that is not parallel to the beam axis at the first stage of the EDMA assembly, using a first AC voltage signal applied at a first frequency. The method may also include blocking a path of a first portion of the ion beam along the beam axis at a blocker, located downstream to the EDMA assembly, wherein a second portion of the ion beam passes the beam blocker as a bunched ion beam. The method may further include deflecting the bunched ion beam at a second stage of the EDMA assembly, downstream to the using a second AC voltage signal applied at the first frequency, wherein a third portion of the beam exits the EDMA assembly.

### BRIEF DESCRIPTION OF THE DRAWINGS

FIG. 1A shows an ion beam processing system, operating according to a first scenario, according to various embodiments of the disclosure;

FIG. 1B shows another ion beam processing system, according to other embodiments of the disclosure;

FIG. 1C shows a computer simulation of ion beamlets, representing B⁺ ions, as transported through the ion beam processing system of FIG. 1B;

FIG. 1D, FIG. 1E, FIG. 1F, and FIG. 1G show computer simulations of ion species transport under the conditions of FIG. 1C for four different ions;

FIG. 2A illustrates one particular embodiment of a convergent ion beam assembly;

FIG. 2B shows another embodiment of a convergent ion beam assembly;

FIG. 3A depicts an EDMA assembly according to further embodiments of disclosure.

FIG. 3B shows a scenario of the operation of an EDMA assembly in conjunction with an electrostatic energy filter;

FIG. 4 shows an exemplary simulated beam profile, depicting beam current as a function of time, for an ion beam generated by an EDMA assembly arranged according to the present embodiments;

FIG. 5A depicts an energy spread for a Boron ion beam in an EDMA assembly without an asymmetric deflection assembly;

FIG. 5B depicts an energy spread for a Boron ion beam in an EDMA assembly with an asymmetric deflection assembly according to the present embodiments;

FIGS. 6A-6C illustrate the operation of an EDMA assembly under one scenario, according to an embodiment of the disclosure;

FIG. 6D-6F illustrate the operation of the EDMA of FIG. 6A under a second scenario;

FIGS. 7A-7C illustrate an embodiment of operation of the EDMA of FIG. 6A under a third scenario;

FIGS. 8A-8C illustrate the operation of a variant of the EDMA of FIG. 6A where the length of the RF electrodes in the first stage differs from the length of the RF electrodes of the second stage;

FIGS. 9A-9C illustrate an embodiment where the parameters for the simulation of FIG. 9A are the same as the parameters specified for FIG. 6A, except that the length of a second stage is adjusted;

FIG. 10 presents a process flow, according to embodiments of the disclosure;

FIG. 11 presents another process flow, according to other embodiments of the disclosure; and

FIG. 12 presents another process flow, according to further embodiments of the disclosure.

The drawings are not necessarily to scale. The drawings are merely representations, not intended to portray specific parameters of the disclosure. The drawings are intended to depict exemplary embodiments of the disclosure, and therefore are not be considered as limiting in scope. In the drawings, like numbering represents like elements.

### DETAILED DESCRIPTION

An apparatus, system and method in accordance with the present disclosure will now be described more fully hereinafter with reference to the accompanying drawings, where embodiments of the system and method are shown. The system and method may be embodied in many different forms and are not to be construed as being limited to the embodiments set forth herein. Instead, these embodiments are provided so this disclosure will be thorough and complete, and will fully convey the scope of the system and method to those skilled in the art.

As used herein, an element or operation recited in the singular and proceeded with the word “a” or “an” are understood as potentially including plural elements or operations as well. Furthermore, references to “one embodiment” of the present disclosure are not intended to be interpreted as precluding the existence of additional embodiments also incorporating the recited features.

Provided herein are approaches for mass analyzed ion implantation systems, using a novel EDMA apparatus.

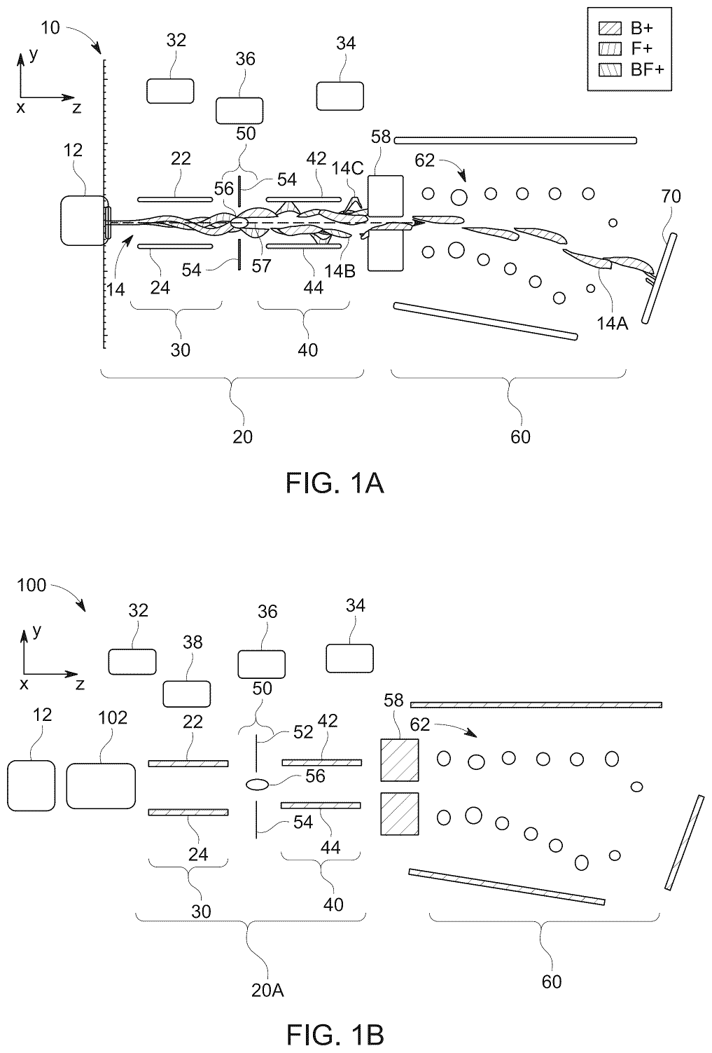

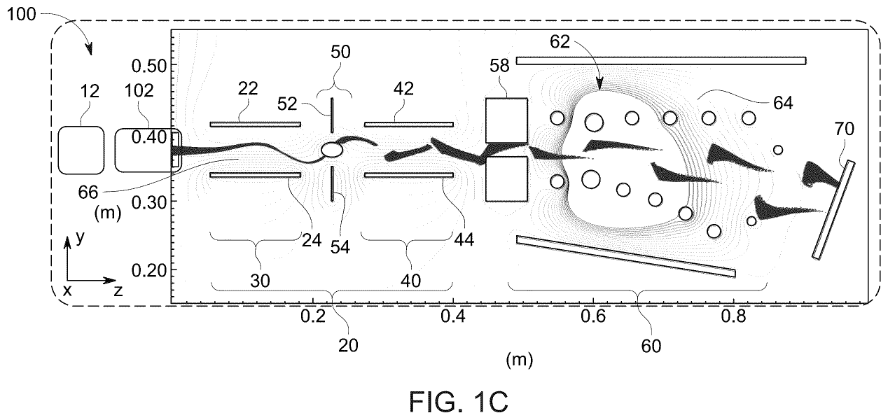

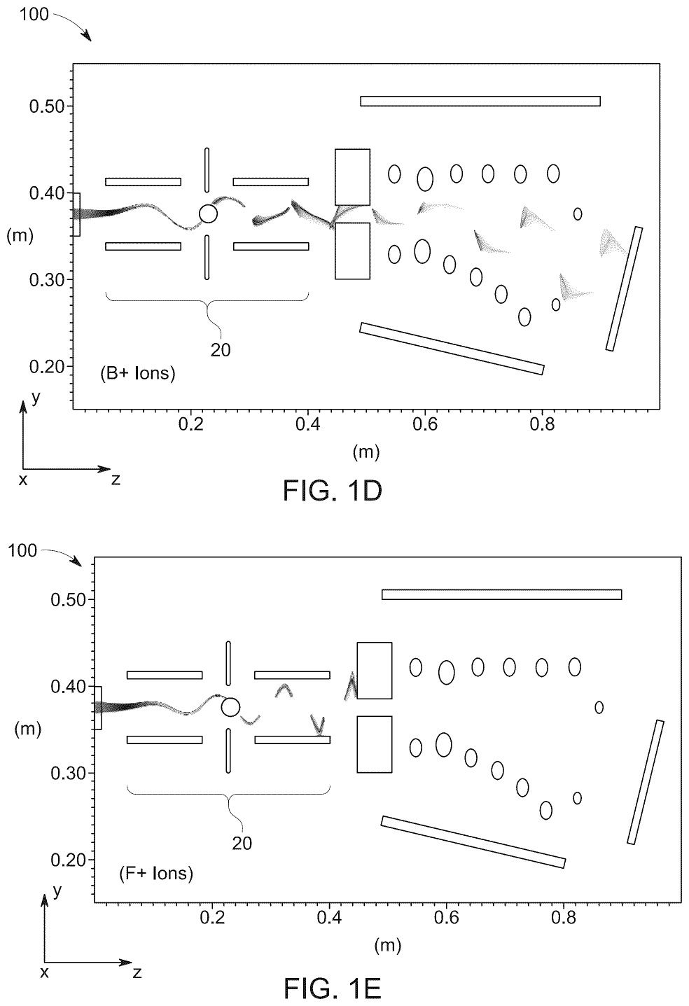

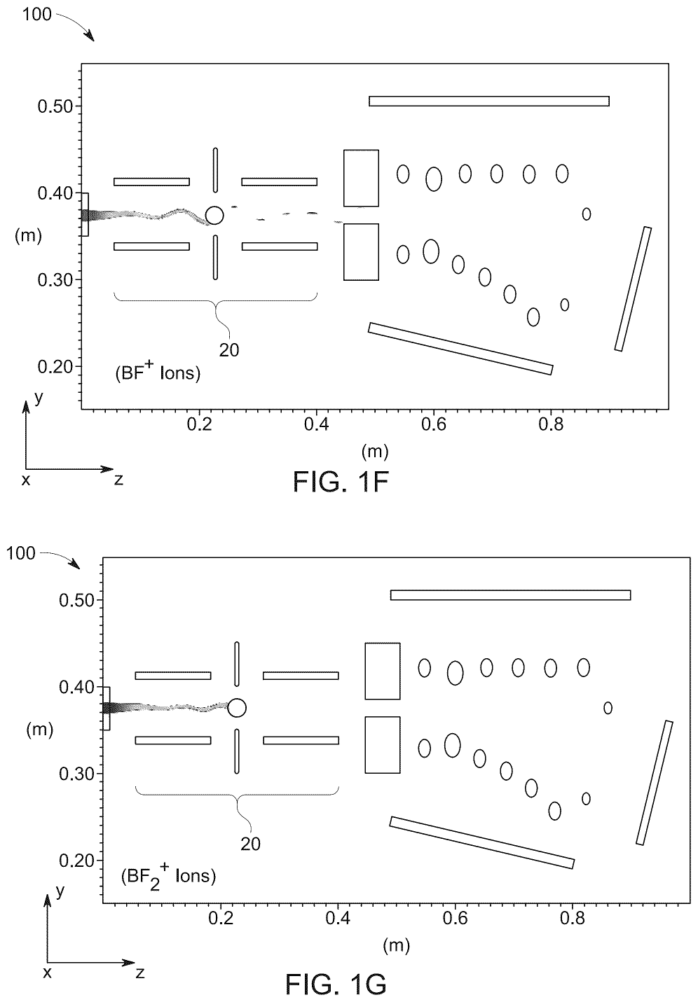

FIG. 1A shows an ion beam processing system 10, according to various embodiments of the disclosure. The ion beam processing system 10 includes an ion source chamber 12, to generate an ion beam 14 as a continuous ion beam, an EDMA assembly 20, disposed to receive the ion beam 14, and generate a mass analyzed ion beam, as well as an electrostatic energy filter, shown as electrostatic energy filter 60, arranged to generate an energy filtered, mass analyzed ion beam that is directed to a substrate 70, shown as ion beam 14A. The structure and operation of an electrostatic energy filter is well known, so details of the electrostatic energy filter 60 will be omitted herein. The basic operation of such an energy filter employs a set of electrodes 62 that are disposed around an ion beam path, where the electrodes 62 apply a series of targeted DC (static) voltages to deflect an ion beam, as well as accelerate and/or decelerate the ion beam. In so doing, the electric fields generated in the electrostatic energy filter 60 will filter out ion species and energetic neutral species having an unwanted energy, different than a targeted energy or targeted range of energies. The general function of the EDMA assembly 20 is to filter out ions of unwanted mass (impurity ion species) and to transmit targeted ions species of a targeted mass into the energy filter 60.

According to various embodiments of the disclosure, the EDMA assembly 20 may include a first stage 30, to receive the ion beam 14. As received, the ion beam 14 may have a trajectory along a beam axis, meaning along the Z-axis in the Cartesian coordinate system shown. The first stage 30 may apply a first RF signal between a first upper electrode 22 and a first lower electrode 24. In various non-limiting embodiments, suitable frequencies for RF signals of the present disclosure may be in the range of 200 kHz to 100 MHz.

As detailed in the discussion to follow, the first RF signal will deflect the ion beam 14 in a manner that aids in mass filtering. The EDMA assembly 20 may further include a second stage 40, disposed downstream of the first stage 30, to apply a second RF signal between a second upper electrode 42 and a second lower electrode 44. This second stage 40 may be arranged similarly to the first stage 30 in some embodiments, while in other embodiments, the second stage 40 may differ from the first stage 30 in at least one aspect.

In some embodiments, the electrodes of the first stage 30 and second stage 40 are elongated along an electrode axis (represented by the X-axis) where the electrode axis extends perpendicularly to the beam axis. This configuration may be especially suitable for treating ribbon beams, where the ribbon beam is characterized by a long axis in cross-section extending along the X-axis. However, in other embodiments the electrodes of the first stage 30 and second stage 40 may be shaped to treat a spot or pencil beam having a more equiaxed shape in cross-section.

The EDMA assembly 20 may further include a deflection assembly 50, disposed between the first stage 30 and the second stage 40, and comprising a blocker 56. As shown in FIG. 1A, the blocker 56 may be disposed along the beam axis 57, which axis may represent a midline between upper electrodes of the first stage 30 and second stage 40 and lower electrodes of the first stage 30 and second stage 40, according to some embodiments. In some embodiments, the deflection assembly 50 may include an upper deflection electrode 52, disposed on a first side of the blocker 56, and a lower deflection electrode 54, disposed on a second side of the blocker 56. Note that for clarity of illustration, in FIG. 1A and other figures certain walls are omitted that form part of the EDMA assembly 20 or similar EDMA apparatus.

As illustrated in FIG. 1A, in operation, the EDMA assembly 20 may perform a mass filtering operation on the ion beam 14 by deflecting constituent ions of the ion beam 14 along different trajectories, so as to intercept ions whose mass does not correspond to the targeted ion mass, while transmitting ions of the targeted mass through to the energy filter 60. In FIG. 1A a computer simulation of ion beamlets is shown, representing three different ion species having different mass, in this case B⁺ ions, F⁺ ions and BF⁺ ions, where the target ions for implanting into the substrate 70 are the B⁺ ions. The incident ion beam, meaning that the ion beam 14, before entering EDMA assembly 20, may include portions of each of these ion species. Upon passing through the EDMA assembly 20, a large fraction of the F⁺ ions and BF⁺ ions are deflected in a manner that causes these ions to be intercepted by components in the EDMA assembly 20, so as not to be transmitted to the energy filter 60. In the simulation shown, a 3m A, 20 kV input B⁺ current is filtered so that a transmission of approximately 50% B+current is realized at the substrate 70. In other words, approximately 50% of the B⁺ ions are deflected in a manner that causes the B⁺ ions to travel around the blocker 56 and exit the EDMA assembly 20 at positions near to the beam axis 57 without being intercepted be structures such as exit tunnel 58. At the same time, as illustrated in FIG. 1A, ions of the ion beam 14, after encountering the blocker 56, may exit the EDMA assembly 20 in a plurality of bunches, rather than as a continuous ion beam.

Recall the ion beam 14 is made of individual ions traveling with a velocity determined by the energy and mass, where the ions are travelling generally along the beam axis 57 during entry into the first stage 30, in the embodiment of FIG. 1A. During operation of the EDMA assembly 20, an AC (RF) voltage signal is applied in the first stage 30 to generate a sinusoidally varying time-dependent field in the vertical direction (Y-axis) with a given maximum amplitude. The AC signal is applied in a manner so that at any given instance, the first upper electrode 22 is driven by a first voltage signal that is out of phase with a second voltage signal at the first lower electrode 24. The phase shift between the first voltage signal may be ideally 180 degrees, or close to 180 degrees, such as 175 degrees, 178 degrees, or 179 degrees according to some non-limiting embodiments. This phase shift establishes a time-dependent electric field along the Y-axis. Said differently, the equipotential field lines of such an electric field will generally lie parallel to the x-z plane in the Cartesian coordinate system shown. A similar scenario takes place at the second upper electrode 42 and second lower electrode 44. As shown by the various bunches of ion beams, representing different arrival times, corresponding to different phases of the AC signal, some portions of the ion beam 14 return to the original line of flight and the original angle, oriented along the beam axis 57, regardless of the phase (arrival time) for different ions, or sufficiently close to the beam axis 57 and the original trajectories along the Z-axis, so as to exit the EDMA assembly 20. Other portions of the ion beam 14, representative of BF⁺ ions and F⁺ ions, are deflected to positions and/or trajectories that cause these other portions to be captured within the EDMA assembly 20.

In particular, as the ion beam 14 traverses the first stage 30, the position and trajectories of constituent ions of the ion beam 14 will fluctuate in accordance with the magnitude and frequency of the applied AC (RF) signal. In the example of a sinusoidal RF signal, the ion beam 14 may assume a sinusoidal-like or wavelike shape in the first stage. Different portions of the ion beam, characteristic of different species having different masses, will tend to propagate as waves with different amplitudes, where portions of the waves are blocked by the blocker 56. As a result, the ion beam 14 will tend to be arranged in bunches after passing the blocker 56 as shown. Moreover, the EDMA assembly 20 may be set to favor propagation of bunches associated with an ion species of a targeted mass, as detailed more in the discussion to follow.

Advantageously, a first stage power supply 32 may be arranged to apply a first RF voltage signal between the first upper electrode 22 and the first lower electrode 24, while a second stage power supply 34 is arranged to apply a second RF voltage signal between the second upper electrode 42 the second lower electrode 44. A controller 38 may also be provided, to independently vary a first magnitude of the first RF voltage signal with respect to a second magnitude of the second RF voltage signal. The controller 38 may also be arranged to vary a first phase of the first RF voltage signal with respect to a second phase of the second RF voltage signal. This flexibility allows the properties of an ion beam that is processed by the EDMA assembly 20 to be tailored according to an application, to improve current yield, mass filtering, and/or energy spread of transmitted ions, for example.

One issue encountered by operating the system of FIG. 1A is that when a parallel ion beam with ion trajectories generally parallel to one another is directed into EDMA assembly 20, as beam current increases, space charge effects will tend to decrease the ability of the EDMA assembly 20 to transmit ions of a targeted mass. In one simulation of a 15 mA, 20 kV input B⁺ current ion beam that is directed to the EDMA assembly 20, the resulting transmitted ion beam exhibited just 20% of the original beam current was observed, as well as a relatively higher transmission of F⁺ ions in the transmitted ion beam.

Turning to FIG. 1B there is shown another ion beam processing system, shown as ion beam processing system 100, according to other embodiments of the disclosure. In this embodiment, in addition to the aforementioned components of the embodiment of FIG. 1A, including the electrostatic energy filter 60 and EDMA assembly 20, the ion beam processing system 100 includes a convergent ion beam assembly 102. The convergent ion beam assembly 102 is arranged to generate a convergent ion beam that is received by the EDMA assembly 20. Advantages of this configuration are explained further with respect to FIG. 1C.

In various embodiments a deflection power supply 36 may be provided, where the deflection power supply 36 is arranged to apply a static bias voltage between the blocker 56 and the upper deflection electrode 52 and lower deflection electrode 54 of the deflection assembly 50. For example, the blocker 56 may be set at ground or negative potential, while the upper deflection electrode 52 and lower deflection electrode 54 are both set at a positive potential with respect to ground, such as +1 kV, +1.5 kV, +2 kV, or any potential suitable according to the mass and energy of an ion species to be guided through the EDMA assembly 20.

Turning to FIG. 1C, a computer simulation of ion beamlets is shown, representing B⁺ ions, as transported through the ion beam processing system 100. In this simulation, an 18 mA 20 kV B⁺ ion beam is directed from the convergent ion beam assembly 102 into the EDMA assembly 20 as a convergent ion beam 66. Note that while the ion beam is referred to as a “B⁺ ion beam, the ion beam also includes BF⁺, BF₂⁺ and F⁺, but the simulation just shows the B⁺ component of the beam.

A first RF voltage signal is applied between the first upper electrode 22 and first lower electrode 24 at a frequency of 4 MHz and a peak amplitude of 7.5 kV. A second RF voltage signal is applied between the second upper electrode 42 and the second lower electrode 44 also at a frequency of 4 MHz and a peak amplitude of 7.5 kV. Note that in this embodiment, the phase of the first RF voltage signal and second RF voltage signal are such that the potential at the first upper electrode 22 is always the same as the potential at the second upper electrode 42, while the potential at the first lower electrode 24 is always the same as the potential at the second lower electrode 44. Again the phase of the first RF signal and second RF signal as received at the first upper electrode 22 and second upper electrode 42 is 180 degrees shifted from the phase of the first RF signal and second RF signal as received at the first lower electrode 24 and second lower electrode 44. A deflection voltage at +1.5 kV potential is applied to the upper deflection electrode 52 and lower deflection electrode 54, while the blocker 56 is grounded. An instantaneous depiction of the electric fields generated is shown as equipotential field lines 64.

Because the ion beam is directed as a convergent ion beam 66 as shown in FIG. 1C, this geometry will compensate for the space charge blow-up in the first stage 30 of the EDMA assembly 20, especially for higher beam currents, such as 18 mA in the example shown. Note that in many cases, a B⁺ beam as generated from an ion source will include F⁺ species as well as BF⁺ species, which species are heavier and will be present in greater amounts in the first stage 30, tending to generate the strongest space charge effects. These heavy/space charge-contributing species will tend to be filtered out to a substantial degree by the deflection assembly 50, including the blocker 56. In addition, the biasing of the blocker 56 with respect to upper deflection electrode 52 and lower deflection electrode 54 may provide the ability to adjust for space charge driven excessive deflection of the desired ion species, such as B⁺ in the first stage 30. As a result, the percent transmission of the B⁺ beam may improve as compared to the embodiment of FIG. 1A.

Turning to FIG. 1D, FIG. 1E, FIG. 1F, and FIG. 1G there is shown a computer simulation ion species transport under the conditions of FIG. 1D, described above, for a boron ion beam and the constituent species, corresponding to B⁺, F⁺, BF⁺, and BF₂⁺, respectively. As qualitatively shown, a relatively larger fraction of the B⁺ ion current is transported through to the substrate 70 (see FIG. 1C for individual elements with reference numbers, omitted here for clarity). Regarding F⁺ ion species, a relatively large fraction of the incident current passes into the second stage 40 (see FIG. 1C). However, due to the heavier mass of r with respect to B⁺, the fields within the EDMA are such that the F⁺ ion current is deflected in a manner so as not to enter the electrostatic energy filter 60. Regarding the heavier ion species (BF₂⁺ and most of BF⁺ ions), mainly contributing to the space charge effects, these ions are mostly filtered at the first stage 30. For example, the BF₂⁺ current is not deflected substantially in the Y direction, such that the current is essentially entirely intercepted by the blocker 56.

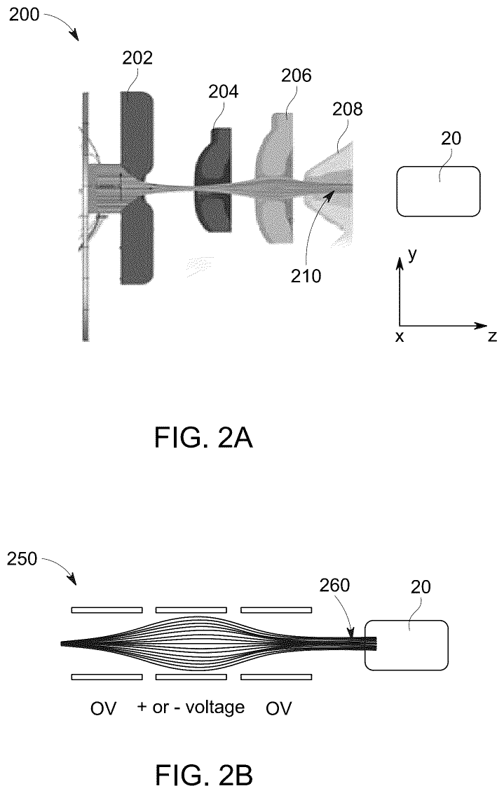

Regarding the convergent ion beam assembly 102, in various embodiments this assembly may be constructed according to any suitable known apparatus that generates a converging ion beam. FIG. 2A illustrates one particular embodiment of a convergent ion beam assembly 200, formed from a tetrode assembly. The convergent ion beam assembly 200 may include a first electrode 202, such as a plate of an ion source, which plate is biased at final beam energy. A suppression electrode 204 is biased negatively with respect to the first electrode 202 in order to extract an ion beam. A ‘defocusing’ electrode 206 is biased positively with respect to the suppression electrode 204 to slow down the ion beam and increase the beam vertical size, and a ‘ground’ electrode 208 is provided at beamline potential to generate a convergent ion beam 260 entering an EDMA assembly 20.

Note, this configuration is different from known tetrode extraction assemblies, where a defocusing electrode, analogous to defocusing electrode 206, is kept negative with respect to the beamline to keep a beamline neutralized. However, such neutralization is not the necessary for operation of the EDMA assembly 20.

In another embodiment, shown in FIG. 2B, a convergent ion beam assembly 250 may be configured as an Einzel lens, with three sets of electrodes as shown, where the middle electrode is biased with respect to the first electrode and the last electrode, in order to generate a convergent ion beam 260.

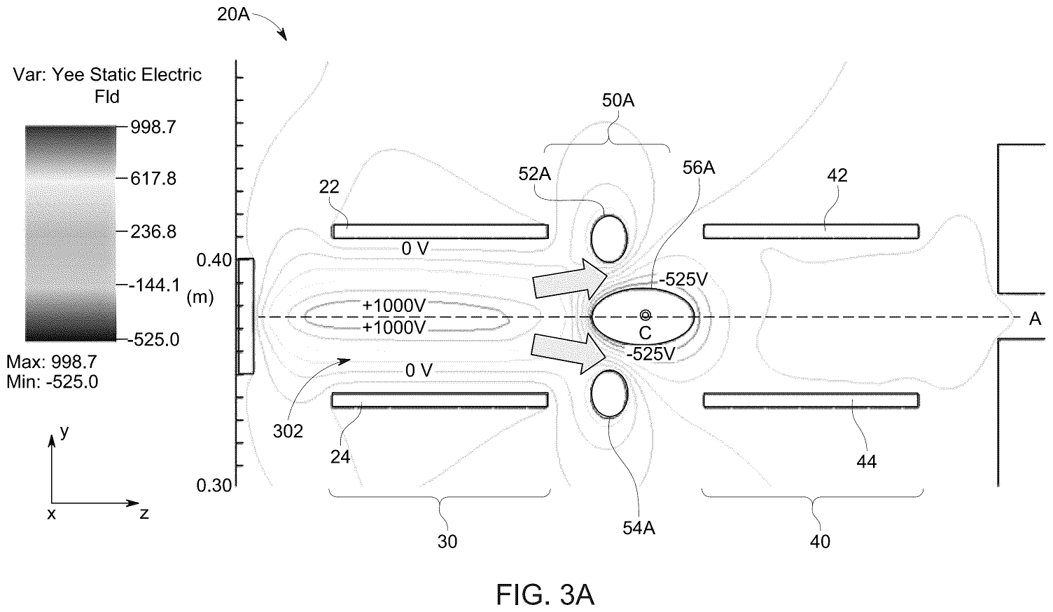

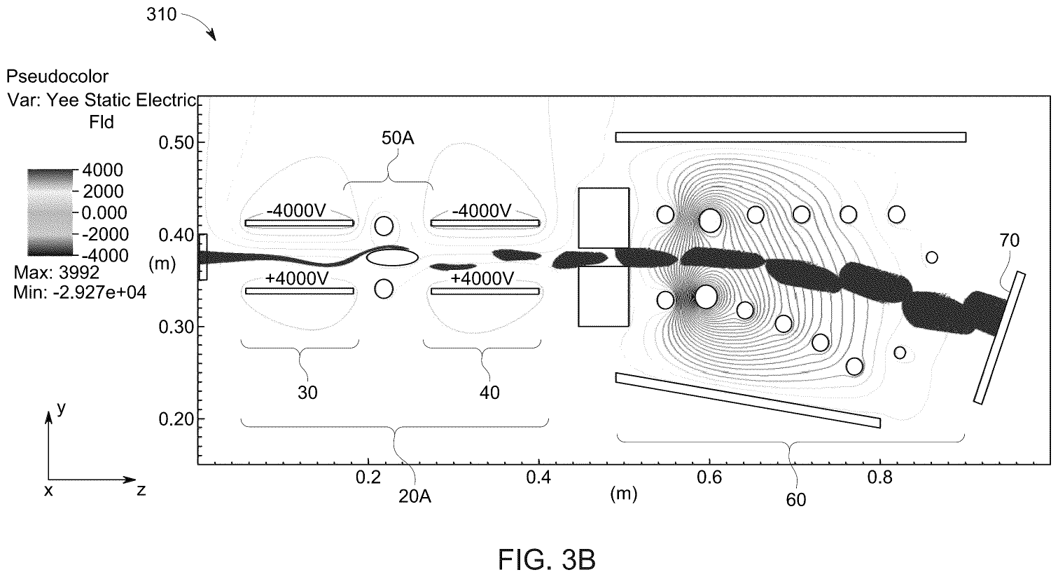

FIG. 3A depicts an EDMA assembly 20A according to further embodiments of disclosure. In this example, the first stage 30 and the second stage 40 may be configured as described previously. A deflection assembly 50A is provided, wherein a center C of a blocker 56A is disposed downstream with respect to the upper deflection electrode 52A and the lower deflection electrode 54A. In this example, the upper deflection electrode 52A and the lower deflection electrode 54A may be configured as rods (elongated in the X-direction) having an elliptical cross-section as shown. The blocker 56A may also be configured as a rod (elongated in the X-direction) having an elliptical cross-section as shown, where the center C of the ellipse is located downstream of the upper deflection electrode 52A and the lower deflection electrode 54A. The FIG. 3A also depicts the electric fields 302 present when 0V potential difference exists between the first upper electrode 22 and first lower electrode 24. The deflection of ions in this scenario may be termed asymmetric deflection because of the asymmetry of the blocker 56A with respect to the positions of the upper deflection electrode 52A and the lower deflection electrode 54A. In particular, even when no RF potential is present, an electrostatic field will be present because the heavy ion species are assumed to introduce a ˜1 kV potential along the axis of symmetry A, referred to previously as the beam axis. Thus, at 0V instantaneous applied RF voltage between the first upper electrode 22 and the first lower electrode 24, a 1 kV field is present in the middle between these electrodes as shown. This potential gives an extra kick to B⁺ ions in the up or down direction compared to a no-space charge case.

Turning now to FIG. 3B there is shown a scenario of the operation of an EDMA assembly in conjunction with electrostatic energy filter 60, where a 21 kV 18 mA input B⁺ beam is directed from a convergent ion beam assembly into the EDMA assembly 20. A 4 MHz first RF voltage signal is applied between the first upper electrode 22 and first lower electrode 24 with a maximum amplitude of 4 kV. Similarly, a 4 MHz first RF voltage signal is applied between the second upper electrode 42 and second lower electrode 44 with a maximum amplitude of 4 kV. A +525 V potential is applied to the upper deflection electrode 52A and lower deflection electrode 54A, while the blocker 56A is kept at −525V potential.

In FIG. 3B, the voltage applied to the deflection assembly 50A is used to compensate for the extra ‘kick’ to B⁺ ions generated by space charge from heavy ions, especially in the first stage 30, as detailed at FIG. 3A. Note that when the configuration of FIG. 1C is used, where the blocker 56 is not located downstream with respect to upper deflection electrode 52 and lower deflection electrode 54, this ‘symmetric’ deflection was observed to overcompensate for the ‘kick’ from space charge at the second stage 40. In contrast, in FIG. 3B, an asymmetric deflection is generated that corrects the trajectories and location of a convergent B⁺ beam (ion beam 310) mainly before the convergent ion beam 66 reaches the second stage 40. As a result, in addition to excellent mass filtering, the EDMA assembly 20A provides a relatively higher percentage transmission of the ion beam 310 to the substrate 70 in comparison to a configuration with a symmetric deflection assembly as in FIG. 1C.

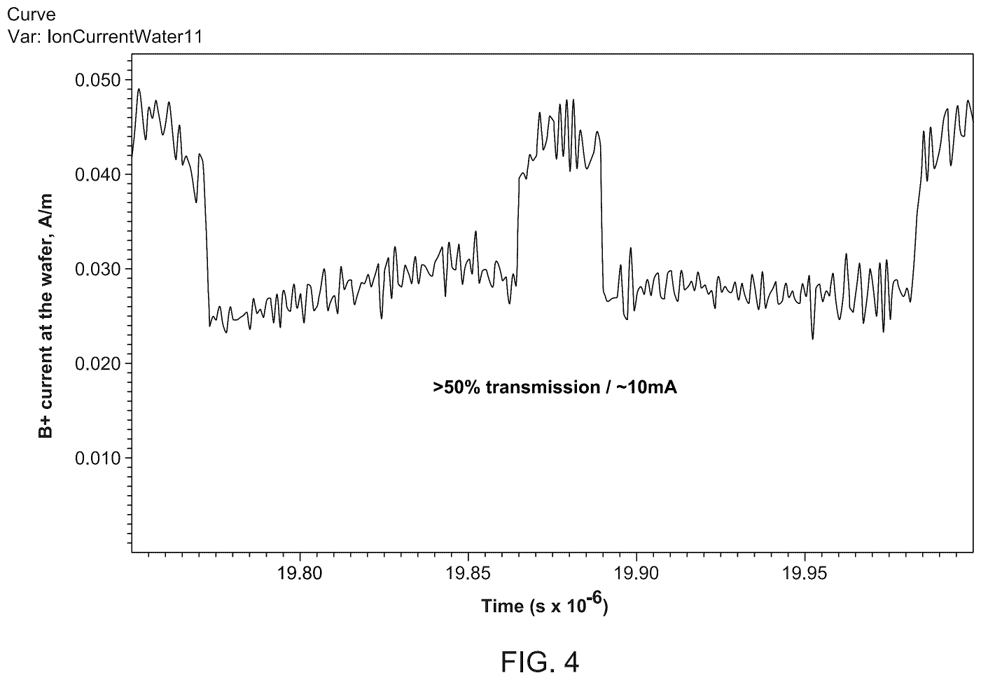

Turning to FIG. 4, there is shown an exemplary simulated beam profile, depicting beam current as a function of time, for an ion beam generated by an EDMA assembly arranged according to the present embodiments. The beam current varies as a function of time, in pulses that reflect the deflection of a continuous ion beam that is deflected into different trajectories and locations, as shown in FIG. 3B. This current represents a current yield of greater than 50% with respect to input beam current into the EDMA assembly.

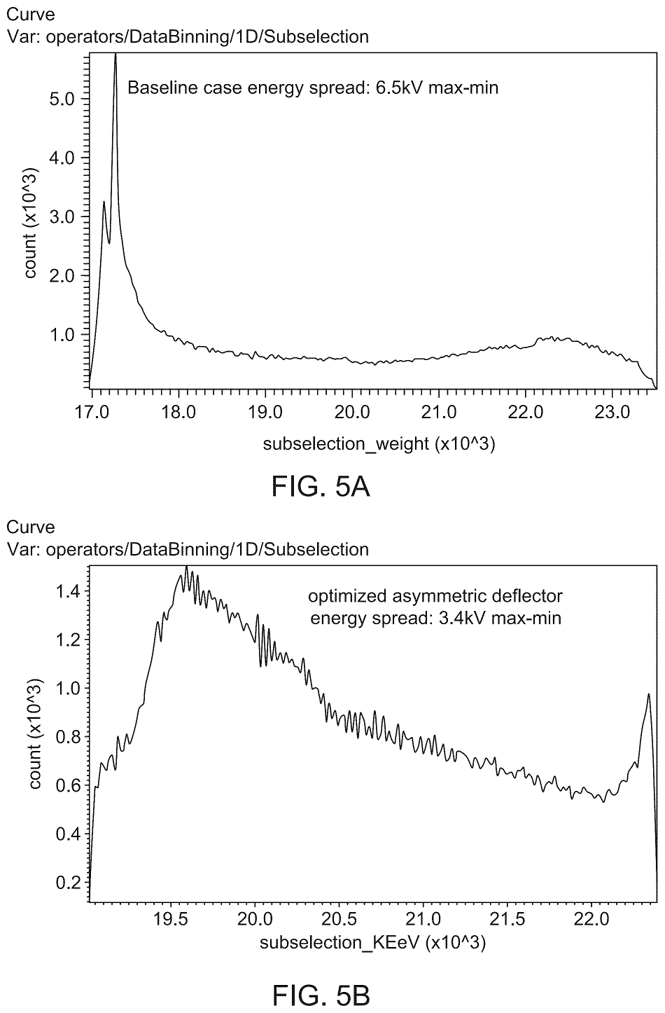

While an EDMA configuration may provide a compact and convenient manner to achieve mass analysis, one issue encountered with the use of an EDMA assembly is the energy spread of filtered ions of a given targeted mass. FIG. 5A depicts an energy spread for a Boron ion beam in an EDMA assembly without an asymmetric deflection assembly, where the maximum-to-minimum energy spread is 6.5 kV.

FIG. 5B depicts an energy spread for a Boron ion beam in an EDMA assembly with an asymmetric deflection assembly according to the present embodiment, where the maximum-to-minimum energy spread is 3.4 kV. The simulated conditions in FIG. 5A and FIG. 5B are for a 21 kV input ion beam, consisting of 18 mA B⁺, 18 mA BF⁺, 18 mA BF₂⁺, and 8 mA F⁺. The graphs shows energy distribution of the Boron beam component after passing through the EDMA. Thus, the present embodiments facilitate the ability to achieve a substantially smaller energy spread for a filtered ion beam.

As noted previously, embodiments are contemplated where the amplitude of a first RF voltage signal applied to the first stage 30 may be independently varied from the second RF voltage signal applied to the second stage 40, so that the amplitude and/or phase of the first RF voltage signal may be changed with respect to the amplitude and/or phase of the second RF voltage signal.

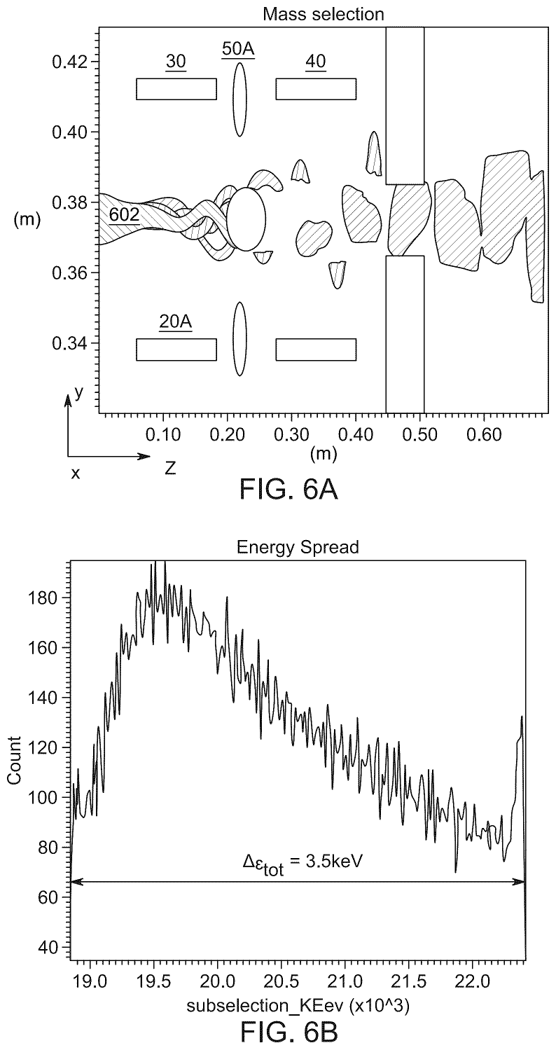

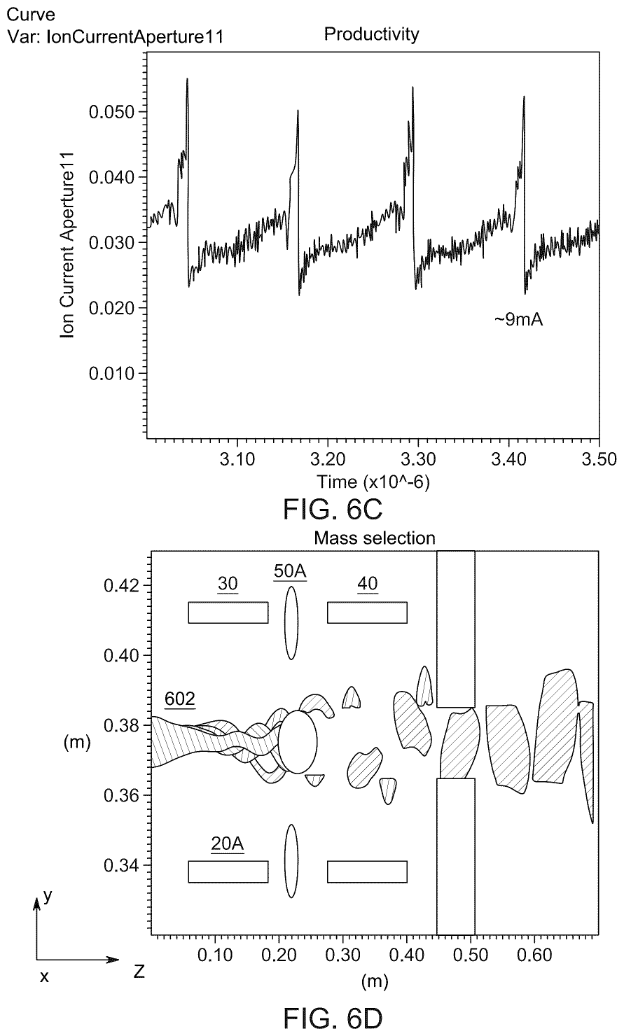

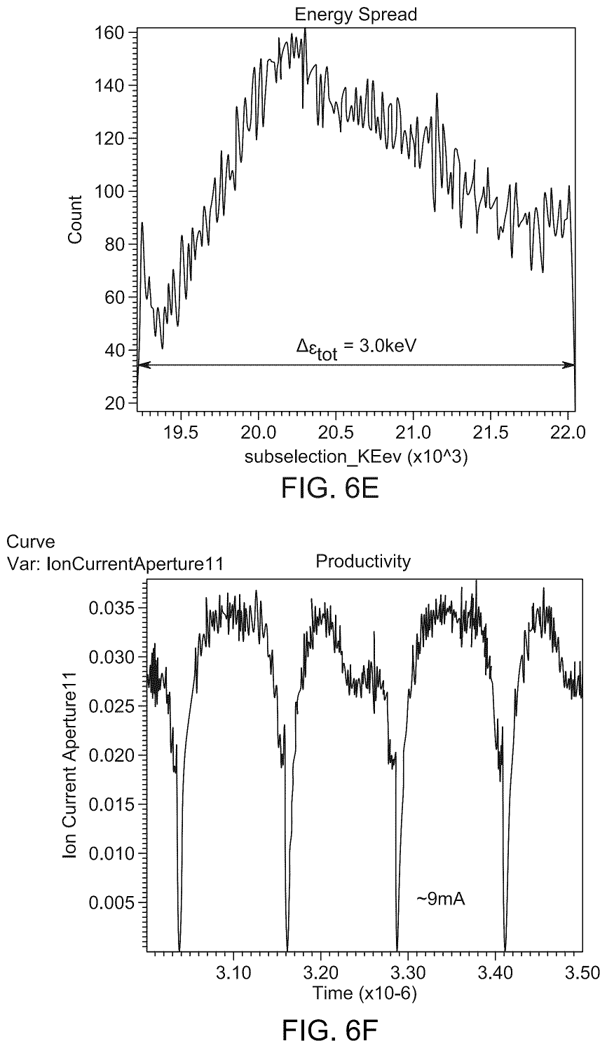

FIGS. 6A-6C illustrate the results of the operation of an EDMA assembly under one scenario, according to an embodiment of the disclosure. FIG. 6D-6F illustrate the results of operation of the EDMA assembly 20A of FIG. 6A under a second scenario, where the operating conditions are the same as the operation conditions of FIG. 6A, except the voltage at the RF electrodes in the first stage 30 are set to a different maximum amplitude from the maximum amplitude of the voltage at the RF electrodes of the second stage 40.

In FIG. 6A, a 21 keV, 18 mA input B⁺ convergent beam 602 is directed through the EDMA assembly 20A with a 4 kV maximum amplitude RF voltage signal provided to the first stage 30, and likewise a 4 kV maximum amplitude RF voltage signal applied to the second stage 40. The two different RF voltage signals are provided with zero degrees phase shift between the two RF voltage signals. In this example, the length of the first stage 30 and length of the second stage 40 along the Z-axis are both 12.5 cm. The convergent ion beam is a B⁺ ion beam having F⁺ and BF⁺ components, as depicted in the computer simulation of FIG. 6A. FIG. 6B depicts the current density as a function of ion energy, showing an energy spread of 3.5 keV. FIG. 6C depicts the current as a function of time at the substrate, which current is the equivalent of 9 mA, such that the current yield is approximately 50%.

In FIG. 6D, a 21 keV, the same 18 mA input B+ convergent beam 602 is directed through the EDMA assembly controller with a 4 kV maximum amplitude RF voltage signal provided to the first stage 30, while a 1 kV maximum amplitude RF voltage signal applied to the second stage 40. The two different RF voltage signals are provided with zero degrees phase shift between the two RF voltage signals. A 600 V DC deflection is provided in the deflection assembly. In this example, the length of the first stage 30 and length of the second stage 40 along the Z-axis are both 12.5 cm. FIG. 6E depicts the current density as a function of ion energy, showing an energy spread of 3.0 keV. FIG. 6F depicts the current as a function of time at the substrate, which current is the equivalent of 9 mA, such that the current yield is approximately 50%. Thus, the lowering of the maximum voltage at the second stage 40 may yield a smaller energy spread to the filtered boron ion beam, at least for the conditions specified.

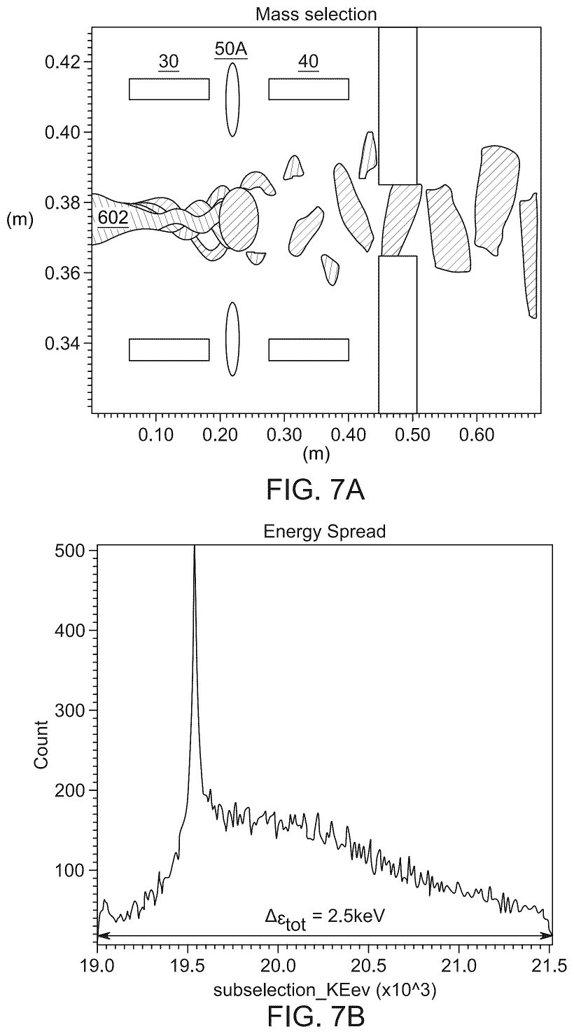

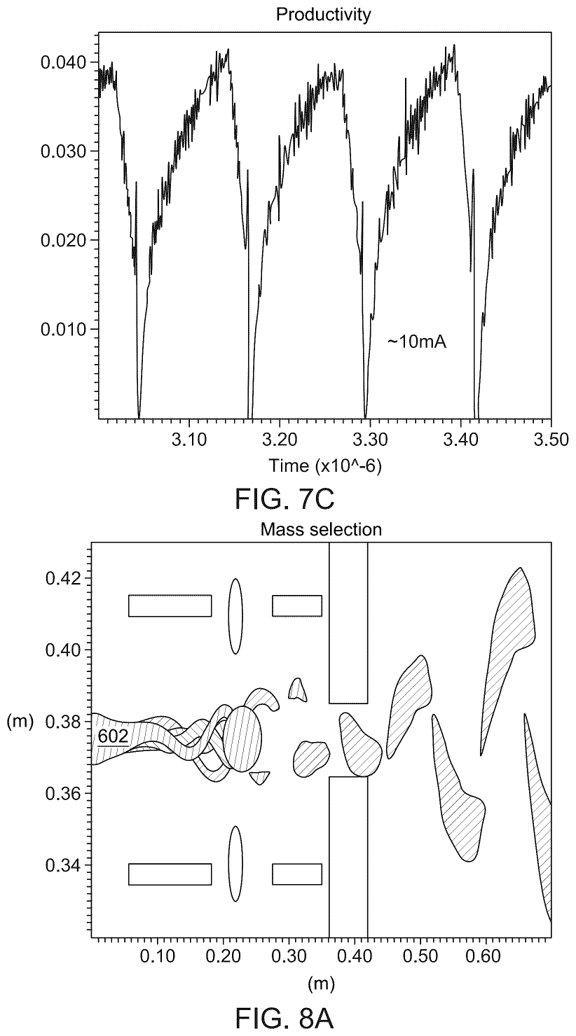

With reference also to FIGS. 6A-6C, the FIGS. 7A-7C illustrate an embodiment where the phase of a voltage signal applied at the RF electrodes in the first stage 30 is set to a different phase with respect to the phase of a voltage signal applied at the RF electrodes of the second stage 40. The parameters for the simulation of FIG. 7A are the same as the parameters specified for FIG. 6A, except that the phase of the RF voltage signal applied to second stage 40 is offset by 60 degrees from the phase of the RF voltage signal applied to the first stage 30. The filtering, meaning the mass selection, in FIG. 7A does not differ substantially from the filtering of the arrangement of FIG. 6A. However, the energy spread is reduced from 3.5 keV to 2.5 keV, as shown in FIG. 7B, while the throughput (FIG. 7C) is increased to ˜10 mA, meaning a transmission percent of approximately 56%.

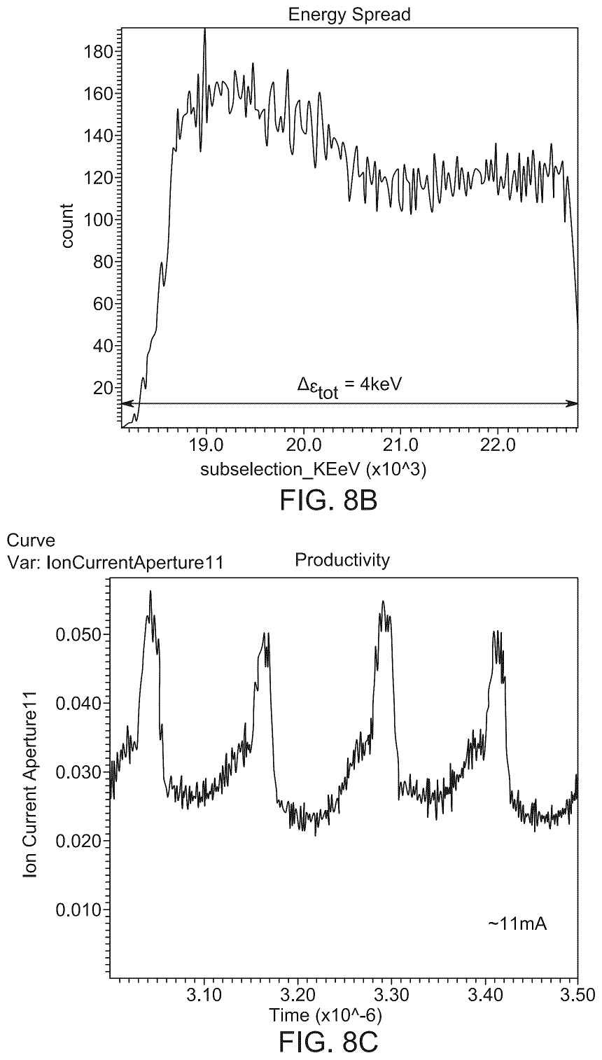

With reference also to FIGS. 6A-6C. the FIGS. 8A-8C illustrate an embodiment where the length of the RF electrodes in the first stage 30 differs from the length of the RF electrodes of the second stage 40. The parameters for the simulation of FIG. 8A are the same as the parameters specified for FIG. 6A, except that the length of the second stage 40 is just 7.6 cm as opposed to the 12.5 cm length of the first stage 30. The filtering, meaning the mass selection, in FIG. 8A does not differ substantially from the filtering of the arrangement of FIG. 6A. In this example the energy spread slightly increases from 3.5 keV to 4 keV, as shown in FIG. 8B, while the throughput (FIG. 8C) is increased to ˜11 mA, meaning a transmission percent of approximately 62%, or a >20% improvement with respect to a configuration where the first stage 30 and second stage 40 length is 12.5 cm.

In view of the above, one of skill in the art will recognize the EDMA configurations of the present embodiments may be adjusted by a combination of physical changes to the electrodes of the different stages, as well as changes in the RF signals applied to the different stages, in order to tailor the parameters of an output ion beam.

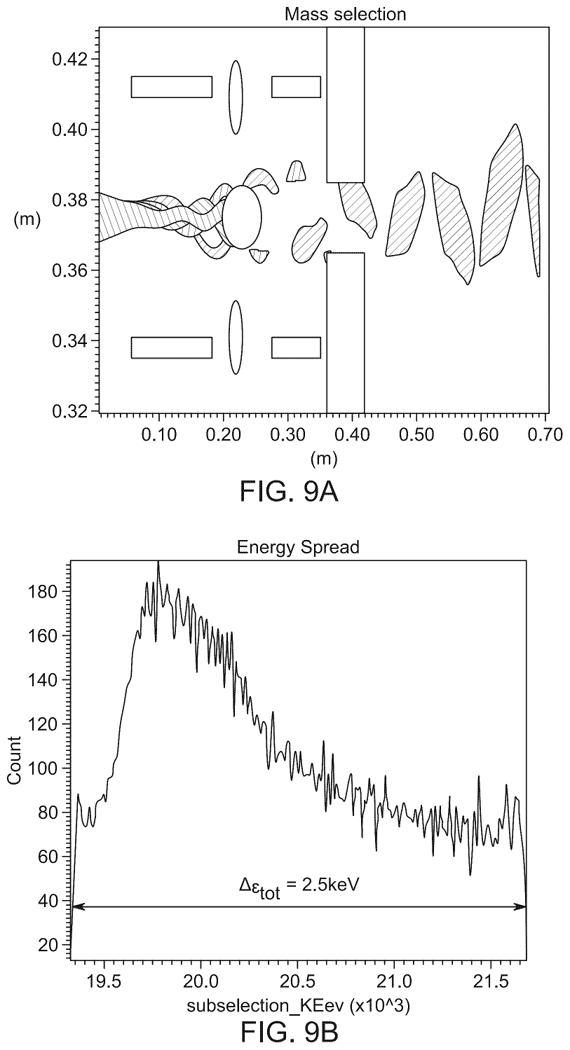

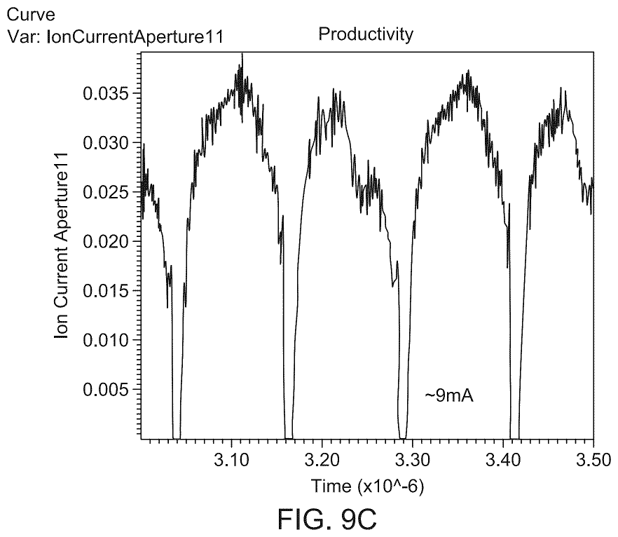

With reference also to FIGS. 6A-6C. the FIGS. 9A-9C illustrate an embodiment where the parameters for the simulation of FIG. 9A are the same as the parameters specified for FIG. 6A, except that the length of the second stage 40 is just 7.6 cm, the maximum amplitude of the voltage applied to the second stage 40 is 1 kV, with a phase offset of 60 degrees between the RF voltage signal at first stage 30 and the RF voltage signal at stage 40. In this example the energy spread slightly decreases from 3.5 keV to 2.5 keV, as shown in FIG. 9B, while the current (FIG. 9C) is similar, ˜9 mA.

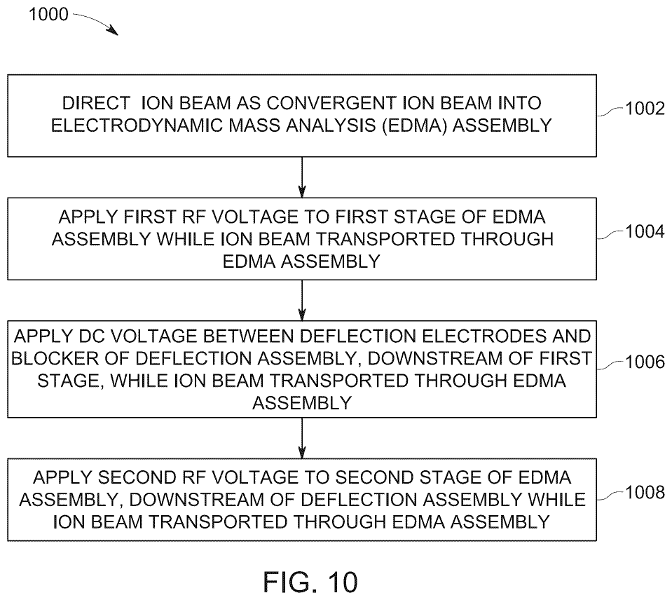

FIG. 10 presents a process flow 1000, according to embodiments of the disclosure. At block 1002, an ion beam is directed as a convergent ion beam into an electrodynamic mass analysis (EDMA) assembly. At block 1004, a first rf voltage is applied to a first stage of the EDMA assembly while the ion beam is transported through the EDMA assembly.

At block 1006, a dc voltage is applied between a set of deflection electrodes and a blocker of a deflection assembly, located downstream of the first stage, while the ion beam is beam transported through the EDMA assembly.

At block 1008, a second rf voltage is applied to a second stage of the EDMA assembly, downstream of the deflection assembly while the ion beam is transported through the EDMA assembly.

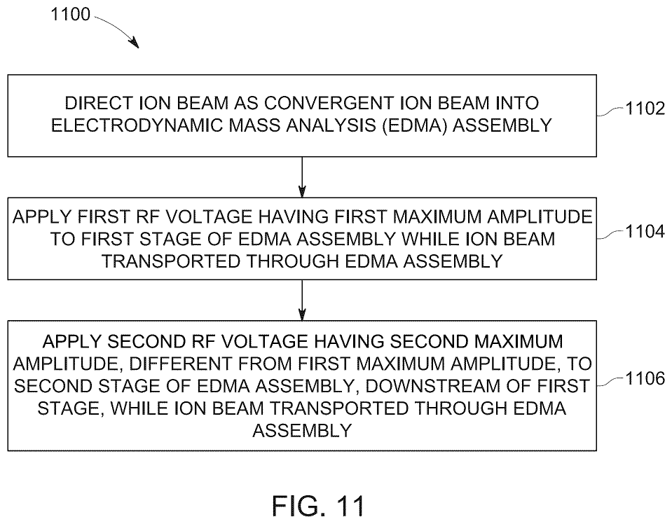

FIG. 11 presents an additional process flow 1100, according to other embodiments of the disclosure. At block 1102, an ion beam is directed as a convergent ion beam into an electrodynamic mass analysis (EDMA) assembly.

At block 1104, a first rf voltage having a first maximum amplitude is applied to a first stage of the EDMA assembly while the ion beam is transported through the EDMA.

At block 1106, a second rf voltage having a second maximum amplitude, different from first the maximum amplitude, is applied to a second stage of the EDMA assembly, where the second stage is located downstream of the first stage, while the ion beam is transported through the EDMA assembly.

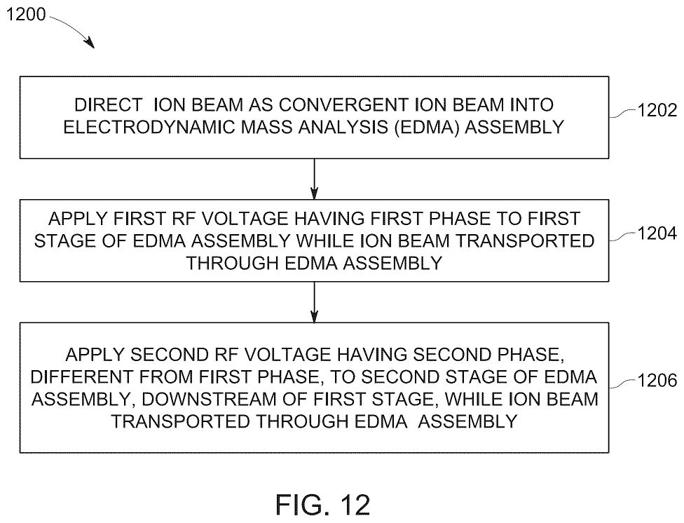

FIG. 12 presents a further process flow 1200, according to other embodiments of the disclosure. At block 1202, an ion beam is directed as a convergent ion beam into an electrodynamic mass analysis (EDMA) assembly. At block 1204, a first rf voltage having a first phase is applied to a first stage of the EDMA assembly while the ion beam is transported through the EDMA assembly.

At block 1206, a second rf voltage having a second phase, different from the first the phase, is applied to a second stage of the EDMA assembly, where the second stage is located downstream of the first stage, while the ion beam is transported through the EDMA assembly.

In view of the foregoing, at least the following advantages are achieved by the embodiments disclosed herein. A first advantage is realized by providing a more compact mass analysis component for mass analyzing an ion beam. A second advantage is expense saved in providing an EDMA type system for mass analysis. A third advantage is the ability to preserve a high degree of mass analysis in an ion beam processed in an EDMA system at relatively higher beam currents, above several mA.

While certain embodiments of the disclosure have been described herein, the disclosure is not limited thereto, as the disclosure is as broad in scope as the art will allow and the specification may be read likewise. Therefore, the above description are not to be construed as limiting. Those skilled in the art will envision other modifications within the scope and spirit of the claims appended hereto.

1. An apparatus, comprising:
an electrodynamic mass analysis (EDMA) assembly, comprising:
a first stage, comprising a first upper electrode, disposed above a beam axis, and a first lower electrode, disposed below the beam axis, opposite the first upper electrode;
a second stage, disposed downstream of the first stage and comprising a second upper electrode, disposed above the beam axis, and a second lower electrode, disposed below the beam axis;
and
a deflection assembly, disposed between the first stage and the second stage, the deflection assembly comprising a blocker, disposed along the beam axis, an upper deflection electrode, disposed on a first side of the blocker, and a lower deflection electrode, disposed on a second side of the blocker.

2. The apparatus of claim 1, wherein a center of the blocker is disposed downstream with respect to the upper deflection electrode and the lower deflection electrode.

3. The apparatus of claim 1, wherein the second upper electrode is shorter than the first upper electrode along a direction parallel to the beam axis, and wherein the second lower electrode is shorter than the first lower electrode along a direction parallel to the beam axis.

4. The apparatus of claim 1, further comprising a first stage power supply, arranged to apply a first RF voltage signal between the first upper electrode and the first lower electrode; and a second stage power supply, arranged to apply a second RF voltage signal between the second upper electrode the second lower electrode.

5. The apparatus of claim 1, further comprising a deflection power supply, arranged to apply a static bias voltage between the blocker and the upper deflection electrode and lower deflection electrode.

6. The apparatus of claim 4, further comprising a controller, arranged to independently vary a first magnitude of the first RF voltage signal with respect to a second magnitude of the second RF voltage signal and arranged to vary a first phase of the first RF voltage signal with respect to a second phase of the second RF voltage signal.

7. An ion beam processing system, comprising:
an ion source chamber, to generate an ion beam as a continuous ion beam;
a convergent beam assembly, to output the ion beam as a convergent ion beam along a beam axis; and
an electrodynamic mass analysis (EDMA) assembly, comprising:
a first stage, to receive the convergent ion beam and apply a first RF signal between a first upper electrode and a first lower electrode;
a second stage, disposed downstream of the first stage, to apply a second RF signal between a second upper electrode and a second lower electrode; and
a deflection assembly, disposed between the first stage and the second stage, and comprising a blocker, disposed along the beam axis, an upper deflection electrode, disposed on a first side of the blocker, and a lower deflection electrode, disposed on a second side of the blocker.

8. The ion beam processing system of claim 7, wherein a center of the blocker is disposed downstream with respect to the upper deflection electrode and the lower deflection electrode.

9. The ion beam processing system of claim 7, wherein the second upper electrode is shorter than the first upper electrode along a direction parallel to the beam axis, and wherein the second lower electrode is shorter than the first lower electrode along a direction parallel to the beam axis.

10. The ion beam processing system of claim 7, further comprising a first stage power supply, arranged to apply the first RF signal between the first upper electrode and the first lower electrode; and a second stage power supply, arranged to apply the second RF signal between the second upper electrode the second lower electrode.

11. The ion beam processing system of claim 7, further comprising a deflection power supply, arranged to apply a static bias voltage between the blocker and the deflection assembly.

12. The ion beam processing system of claim 10, further comprising a controller, arranged to independently vary a first magnitude of the first RF signal with respect to a second magnitude of the second RF signal, and further arranged to vary a first phase of the first RF voltage signal with respect to a second phase of the second RF voltage signal.

13. The ion beam processing system of claim 7, wherein the convergent beam assembly comprises an Einzel lens.

14. The ion beam processing system of claim 7, wherein the convergent beam assembly comprises a tetrode assembly, wherein a third lens of the tetrode assembly is biased positively.

15. The ion beam processing system of claim 7, further comprising an electrostatic energy filter, arranged downstream to the EDMA assembly, and comprising a plurality of electrodes to alter a direction of propagation of the ion beam.

16. A method, comprising;
directing an ion beam as a continuous ion beam along a beam axis into a first stage of an electrodynamic mass analysis (EDMA) assembly;
deflecting the ion beam along a trajectory that is not parallel to the beam axis at the first stage of the EDMA assembly, using a first AC voltage signal applied at a first frequency;
blocking a path of a first portion of the ion beam along the beam axis at a blocker, located downstream to the EDMA assembly, wherein a second portion of the ion beam passes the blocker as a bunched ion beam; and
deflecting the bunched ion beam at a second stage of the EDMA assembly, downstream to the using a second AC voltage signal applied at the first frequency, wherein a third portion of the beam exits the EDMA assembly.

17. The method of claim 16, further comprising applying a deflection voltage between the blocker and a pair of deflection electrodes, disposed on opposite sides of the beam axis.

18. The method of claim 16, wherein the first AC voltage signal comprises a first voltage amplitude, and wherein the second AC voltage signal comprises a second voltage amplitude, less than the first voltage amplitude.

19. The method of claim 16, wherein the first AC voltage signal comprises a first phase, and wherein the second AC voltage signal comprises a second phase, less than the first phase.

20. The method of claim 16, wherein the ion beam is provided to the first stage as a convergent ion beam.

21. The method of claim 16, wherein the first AC voltage signal is applied between a first upper electrode and a first lower electrode, wherein a phase of the first AC voltage signal at the first upper electrode is shifted by 180 degrees from a phase of the first AC voltage signal at the first lower electrode, wherein the second AC voltage signal is applied between a second upper electrode and a second lower electrode, and wherein a phase of the second AC voltage signal at the second upper electrode is shifted by 180 degrees from a phase of the second AC voltage signal at the second lower electrode.

22. The method of claim 16, wherein a target ion species having a first mass exits the EDMA assembly, wherein an impurity ion species having a second mass, different from the first mass does not exit the EDMA assembly along the beam axis, and wherein the ion beam exits the EDMA assembly as a mass analyzed ion beam.
